(19) United States
(12) Patent Application Publication
(10) Pub. No.: US 2015/0084009 A1
(43) Pub. Date: Mar. 26, 2015

(54) ORGANIC LIGHT-EMITTING DISPLAY APPARATUS AND METHOD OF MANUFACTURING THE SAME

(71) Applicant: SAMSUNG DISPLAY CO., LTD., Yongin-City (KR)

(72) Inventor: Chun-Gi You, Yongin-City (KR)

(73) Assignee: SAMSUNG DISPLAY CO., LTD., Yongin-City (KR)

(21) Appl. No.: 14/261,375

(22) Filed: Apr. 24, 2014

(30) Foreign Application Priority Data
Sep. 25, 2013 (KR) 10-2013-0114133

(51) Int. Cl. H01L 51/52; H01L 27/32; H01L 51/56

(52) U.S. Cl. CPC H01L 51/5253; H01L 51/56; H01L 27/3246; H01L 27/3248; H01L 27/3258
USPC 257/40; 438/26

(57) ABSTRACT

An organic light-emitting display apparatus includes: a pixel electrode on a substrate; an environmental element on the pixel electrode; a protection insulating layer between the pixel electrode and the environmental element and at a location corresponding to the environmental element; an opposing electrode facing the pixel electrode; and an intermediate layer between the pixel electrode and the opposing electrode and including an organic emission layer.

### CROSS-REFERENCE TO RELATED APPLICATION

This application claims priority to and the benefit of Korean Patent Application No. 10-2013-0114133, filed on Sep. 25, 2013 in the Korean Intellectual Property Office, the disclosure of which is incorporated herein in its entirety by reference.

### BACKGROUND

1. Field

Aspects of embodiments of the present invention are directed toward organic light-emitting display apparatuses and methods of manufacturing the same.

2. Description of the Related Art

An organic light-emitting display apparatus is a self-luminous display apparatus which includes a plurality of organic light-emitting devices each including a hole injection electrode, an electron injection electrode, and an organic emission layer provided therebetween. An exciton is generated when a hole, injected from the hole injection electrode, is recombined with an electron, injected from the electron injection electrode, in the organic emission layer. Light is then emitted when the exciton falls from an excited state to a ground state.

Because the organic light-emitting display apparatus is a self-luminous display apparatus, a separate light source is unnecessary. Therefore, the organic light-emitting display apparatus may be driven at a lower voltage and be manufactured to have a lighter weight and a slimmer profile. In addition, the organic light-emitting display apparatus has high-grade characteristics, such as wide viewing angles, high contrast, and fast response times. Hence, the organic light-emitting display apparatus has been widely applied to various fields, including personal portable devices such as MP3 players, mobile phones, televisions (TVs), or the like.

### SUMMARY

Aspects of embodiments of the present invention are directed toward organic light-emitting display apparatuses and methods of manufacturing the same.

Additional aspects will be set forth in part in the description which follows and, in part, will be apparent from the description or may be learned by practice of the presented embodiments.

According to one or more embodiments of the present invention, an organic light-emitting display apparatus includes: a pixel electrode on a substrate; an environmental element on the pixel electrode; a protection insulating layer between the pixel electrode and the environmental element and at a location corresponding to the environmental element; an opposing electrode facing the pixel electrode; and an intermediate layer between the pixel electrode and the opposing electrode and including an organic emission layer.

A width of the protection insulating layer may be substantially the same as that of the environmental element.

The protection insulating layer may be between the pixel electrode and the intermediate layer.

The protection insulating layer may include polyimide (PI), silicon oxide, and/or silicon nitride.

The protection insulating layer may have a thickness in a range from about 700 Å to about 1000 Å.

The opposing electrode and the intermediate layer may each include separated regions due to the environmental element.

The organic light-emitting display apparatus may further include: a thin film transistor electrically coupled to the pixel electrode and including an active layer, a gate electrode, a source electrode, a drain electrode, a first insulating layer between the active layer and the gate electrode, and a second insulating layer between the gate electrode and the source and drain electrodes; a pad electrode including a first pad layer on a same layer as the source and drain electrodes, and a second pad layer on the first pad layer; a third insulating layer covering the source and drain electrodes and both edges of the pad electrode and having an opening, the pixel electrode being in the opening; and a pixel defining layer having an opening at a location corresponding to the opening in the third insulating layer, the pixel defining layer covering both edges of the pixel electrode.

The organic light-emitting display apparatus may further include: a capacitor including a first electrode on a same layer as the active layer; a second electrode on a same layer as the gate electrode; and a third electrode on a same layer as the source and drain electrodes.

The pixel electrode may include a transparent conductive oxide layer and a semi-transmissive metal layer including silver (Ag) or a silver alloy, and the opposing electrode may include a reflective metal layer.

The second insulating layer may have an opening at a region corresponding to the opening included in the third insulating layer, wherein the opening in the second insulating layer, the opening in the third insulating layer, and the opening in the pixel defining layer overlap with each other, and wherein the opening in the third insulating layer is larger than the opening in the pixel defining layer and is smaller than the opening in the second insulating layer.

An end portion of the pixel electrode may be on a top surface of the third insulating layer.

The third insulating layer may have a contact hole to electrically couple the pixel electrode with the source electrode or the drain electrode, wherein a first contact layer is electrically coupled to the source electrode or the drain electrode, and a second contact layer is on the first contact layer and includes a same material as that of the second pad layer, the first and second contact layers being disposed at a lower portion of the contact hole, wherein a portion of the pixel electrode is at the contact hole, and wherein the pixel electrode and the second contact layer are directly connected to each other.

According to one or more embodiments of the present invention, a method of manufacturing an organic light-emitting display apparatus includes: forming a pixel electrode on a substrate; forming an insulating material on the pixel electrode; forming a protection insulating layer by removing the insulating material except for a region at which an environmental element is located; forming an intermediate layer on the pixel electrode and the environmental element; and forming an opposing electrode on the intermediate layer.

The method may further include: after the forming of the pixel electrode, forming a pixel defining layer having an opening exposing a portion of the pixel electrode, wherein the forming of the insulating material includes forming the insulating material on the pixel defining layer and on the portion of the pixel electrode exposed by the pixel defining layer.

The insulating material may be formed of polyimide (PI), silicon oxide, and/or silicon nitride.

The insulating material may have a thickness in a range of about 700 Å to about 1000 Å.

The insulating material may be formed by printing.

The intermediate layer and the opposing electrode may be formed by vapor deposition.

The protection insulating layer may be formed by removing the insulating material by plasma treatment.

### BRIEF DESCRIPTION OF THE DRAWINGS

These and/or other aspects of the present invention will become apparent and more readily appreciated from the following description of the embodiments, taken in conjunction with the accompanying drawings in which:

FIG. 1 is a schematic cross-sectional view of an organic light-emitting display apparatus according to an embodiment of the present invention;

FIGS. 2 through 7 are schematic cross-sectional views sequentially explaining a method of manufacturing the organic light-emitting display apparatus shown in FIG. 1, according to an embodiment of the present invention;

FIG. 8 is a schematic cross-sectional view of an organic light-emitting apparatus according to another embodiment of the present invention;

FIG. 9 is a schematic cross-sectional view of an organic light-emitting apparatus according to another embodiment of the present invention; and

FIG. 10 is a schematic cross-sectional view of an organic light-emitting apparatus according to another embodiment of the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

Example embodiments of the present invention will be described below in more detail with reference to the accompanying drawings. Throughout the disclosure, like reference numerals refer to like parts, and a redundant description thereof may be omitted.

It will be understood that although the terms “first”, “second”, etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it may be directly or indirectly formed on the other layer, region, or component. That is, for example, intervening layers, regions, or components may also be present.

Sizes of elements in the drawings may be exaggerated for convenience of explanation. In other words, because sizes and thicknesses of components in the drawings are arbitrarily illustrated for convenience of explanation, the following embodiments are not limited thereto. Expressions such as “at least one of,” when preceding a list of elements, modify the entire list of elements and do not modify the individual elements of the list. Further, the use of “may” when describing embodiments of the present invention relate to “one or more embodiments of the present invention.”

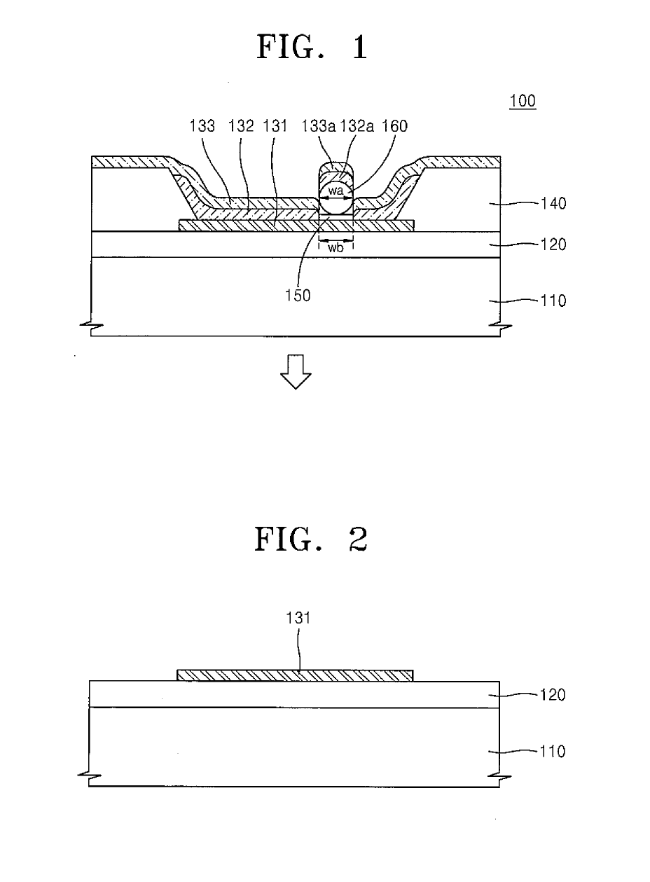

FIG. 1 is a schematic cross-sectional view of an organic light-emitting display apparatus 100 according to an embodiment of the present invention.

Referring to FIG. 1, the organic light-emitting display apparatus 100 of the present embodiment includes a pixel electrode 131 disposed on a substrate 110, an environmental element 160 disposed on the pixel electrode 131, a protection insulating layer 150 disposed between the pixel electrode 131 and the environmental element 160 and disposed at a region of the pixel electrode 131 corresponding to the environmental element 160, an opposing electrode 133 disposed to face (e.g., directly face) the pixel electrode 131, and an intermediate layer 132 disposed between the pixel electrode 131 and the opposing electrode 133 and including an organic emission layer.

An insulating layer 120 may be disposed between the substrate 110 and the pixel electrode 131.

The pixel electrode 131 may be configured as a transparent or semitransparent electrode that transmits light emitted from the organic emission layer included in the intermediate layer 132 and may include a transparent conductive oxide, such as indium tin oxide (ITO), indium zinc oxide (IZO), zinc oxide (ZnO), indium oxide (e.g., In₂O₃), indium gallium oxide (IGO), and/or aluminum zinc oxide (AZO).

The pixel electrode 131 may further include a semi-transmissive metal layer, in addition to the transparent conductive oxide. The semitransparent metal layer may be silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or ytterbium (Yb), and may be formed of a thin film that has a thickness in a range of about 100 Å to about 300 Å.

The pixel electrode 131 may have a structure in which the transparent electrode, the semi-transmissive metal layer, and the transparent electrode are stacked (e.g., sequentially stacked).

The environmental element 160 may be disposed on the pixel electrode 131 and may be an impurity particle provided (e.g., introduced) when the organic light-emitting display apparatus 100 is manufactured. For example, the environmental element 160 may be a microscopic particle introduced from an external environment (for example, dust, mote, etc.), a microscopic particle introduced from manufacturing equipment related to the organic light-emitting display apparatus 100, a microscopic particle introduced from other layers (for example, the substrate 110, the insulating layer 120, etc.) included in the organic light-emitting display apparatus 100, or the like.

The environmental element 160 may have various components (that is, the environmental element 160 have various compositions), such as various organic materials, inorganic materials, combinations of organic and inorganic materials, or the like.

Although the environmental element 160 shown in FIG. 1 is a spherical particle for convenience of illustration, the shape of the environmental element 160 is not limited thereto.

The intermediate layer 132 includes the organic emission layer and may further include at least one of a hole injection layer (HIL), a hole transport layer (HTL), an electron transport layer (ETL), and an electron injection layer (EIL). However, the embodiment of the present invention is not limited thereto, and the intermediate layer 132 may include the organic emission layer and may further include various function (e.g., functional) layers.

The organic emission layer included in the intermediate layer 132 may include an organic material that emits a red color, a green color, or a blue color. However, the embodiment of the present invention is not limited thereto, and the organic emission layer may emit white light. In this case, the intermediate layer 132 may have a stacked structure of light-emitting material emitting red light, light-emitting material emitting green light, and light-emitting material emitting blue light, and may have a combined structure of the light-emitting material emitting red light, the light-emitting material emitting green light, and the light-emitting material emitting blue light.

The red color, the green color, and the blue color are provided as examples, and the present invention is not limited thereto. In other words, other, various suitable color combinations other than the combination of the red, green, and blue colors may be used as long as the combinations can emit white light.

The opposing electrode 133 may be configured as a reflective electrode and may include aluminum (Al), magnesium (Mg), lithium (Li), calcium (Ca), lithium fluoride/calcium (LiF/Ca), and/or lithium fluoride/aluminum (LiF/Al).

Therefore, the organic light-emitting display apparatus 100 according to the present embodiment may be a bottom emission display apparatus in which light emitted from the intermediate layer 132 is reflected by the opposing electrode 133, transmits through the pixel electrode 131, and is emitted in a direction of the substrate 110 (see the arrow in FIG. 1).

When the pixel electrode 131 includes the semi-transmissive metal layer, the semi-transmissive metal layer and the opposing electrode 133 may form a microcavity structure, thereby increasing light efficiency and color purity of the organic light-emitting display apparatus 100.

The organic light-emitting display apparatus 100 of the present embodiment includes the protection insulating layer 150 disposed between the pixel electrode 131 and the environmental element 160.

That is, the protection insulating layer 150 may be disposed only at a region of the pixel electrode 131 at which the environmental element 160 is disposed. A width wa of the environmental element 160 and a width wb of the protection insulating layer 150 may be substantially same.

In this regard, the width wa of the environmental element 160 is a width of a largest cross-sectional region of the environmental element 160. For example, when the environmental element 160 is spherical, a diameter of a sphere may be substantially similar to or the same as the width wa of the environmental element 160.

The environmental element 160 may be a particle having an average particle diameter equal to or less than about 5 μm, for example, between about 1 μm and about 5 μm, but is not limited thereto.

When the environmental element 160 is provided on the pixel electrode 131, the protection insulating layer 150 of the present embodiment may prevent the pixel electrode 131 and the opposing electrode 133 from being shorted (e.g., from contacting one another).

When there is no protection insulating layer 150 and when the environmental element 160 on the pixel electrode 131 is thicker than the intermediate layer 132, the environmental element 160 is not sufficiently covered by the intermediate layer 132, and a region in which the intermediate layer 132 and the opposing electrode 133 are separated (e.g., disconnected or cut) may be generated due to a step difference created by the environmental element 160.

The opposing electrode 133 including aluminum (Al) may diffuse in the separated region (e.g., the cut region) toward the intermediate layer 132 and the pixel electrode 131. Thus, the pixel electrode 131 and the opposing electrode 133 may short or contact one another, which causes a phenomenon in which a corresponding sub pixel does not emit light, i.e., a dark spot.

However, the organic light-emitting display apparatus 100 of the present embodiment includes the protection insulating layer 150 that may block a diffusion path of the opposing electrode 133 and prevent the pixel electrode 131 and the opposing electrode 133 from being shorted. Thus, the phenomenon of the dark spot due to the environmental element 160 may be prevented.

The protection insulating layer 150 may include an organic material, such as polyimide (PI), and/or an inorganic material, such as silicon oxide (e.g., SiO₂) or silicon nitride (e.g., Si₃N₄). However, the present invention is not limited thereto, and the protection insulating layer 150 may include any suitable materials as long as they are insulating materials resistant to moisture.

The protection insulating layer 150 may have a thickness in a range of about 700 Å to about 1000 Å. When the protection insulating layer 150 is formed having a thickness less than 700 Å, the diffusion path of the opposing electrode 133 may not be sufficiently or completely blocked, and, when the protection insulating layer 150 is formed having a thickness greater than 1000 Å, the step difference may be greatly increased and removal of the protection insulation layer 150 by plasma treatment may not be easy.

A separated region (e.g., a cut region) may be included in the intermediate layer 132, and the opposing electrode 133 of the organic light-emitting display apparatus 100 of the present embodiment due to step differences created by the protection insulting layer 150 and the environmental element 160. That is, a separated region 132a (e.g., a separated portion) of the intermediate layer 132 and a separated region 133a (e.g., a separated portion) of the opposing electrode 133 may be disposed on the protection insulting layer 150 and the environmental element 160.

Therefore, no voltage is applied to the region 133a of the opposing electrode 133 disposed on environmental element 160, and thus, no light may emit from the region 132a of the intermediate layer 132 corresponding to the region 133a of the opposing electrode 133. However, a region from which no light emits is a relatively very small region, and light emits from a region in which the environmental element 160 is not disposed, and thus a phenomenon in which entire corresponding sub pixels do not emit light is prevented.

FIGS. 2 through 7 are schematic cross-sectional views sequentially explaining a method of manufacturing the organic light-emitting display apparatus 100 shown in FIG. 1 according to an embodiment of the present invention.

Referring to FIG. 2, the insulating layer 120 and the pixel electrode 131 are formed on the substrate 110. The pixel electrode 131 may be formed by forming a pixel electrode material utilizing a deposition process or a sputtering process and patterning the pixel electrode material by utilizing a photolithography process.

The pixel electrode 131 may be configured as a transparent electrode or a semi-transparent electrode, may include a transparent conductive oxide, and may further include a semi-transmissive metal layer used to form a microcavity structure with the opposing electrode 133 shown in FIG. 1.

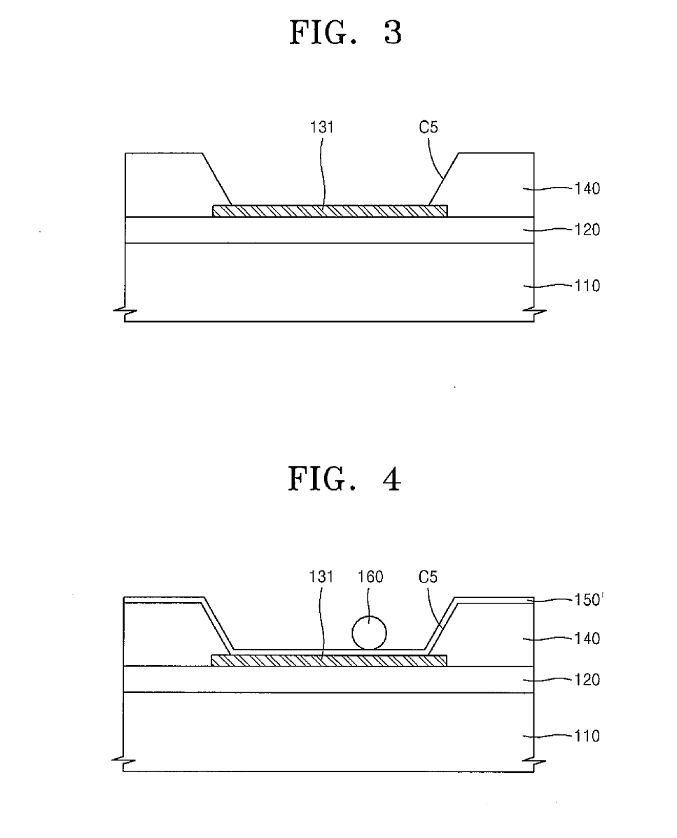

Referring to FIG. 3, a pixel defining layer 140 that includes an opening C5 exposing a part of the pixel electrode 131 and covers both ends of the pixel electrode 131 is formed on the pixel electrode 131.

The pixel defining layer 140 functions to define a pixel region from which light is emitted and may be formed as an organic insulating layer.

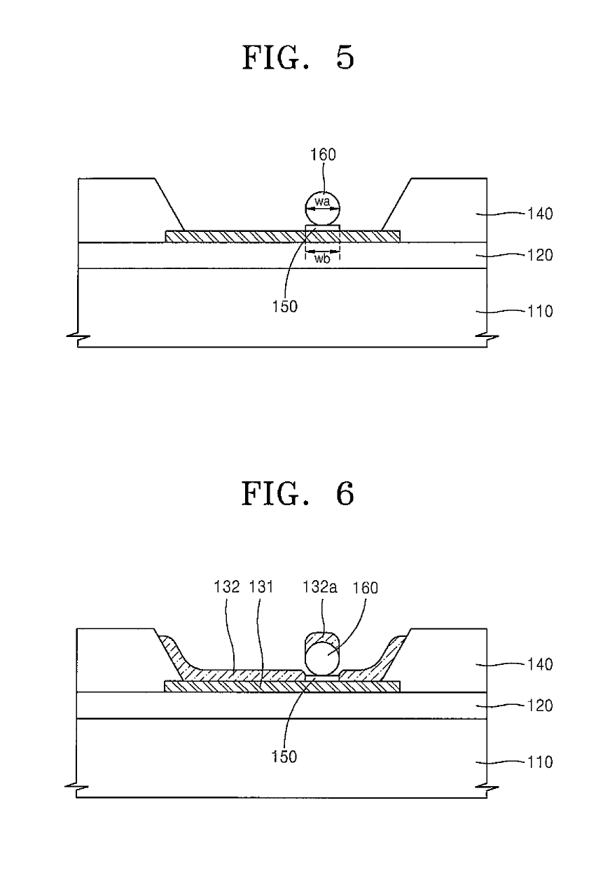

Referring to FIG. 4, an insulating material 150′ used to form the protection insulating layer 150 of FIG. 5 is coated on the pixel defining layer 140 and the pixel electrode 131 that is exposed by the opening C5 formed in the pixel defining layer 140. The insulating material 150′ may be a material resistant to moisture, such as an organic material such as polyimide (PI) or an inorganic material such as silicon oxide or silicon nitride.

The insulating material 150′ may be formed by utilizing a printing process, but the present invention is not limited thereto. The insulating material 150′ may be formed by utilizing other, suitable methods.

The insulating material 150′ may have a thickness in a range of about 700 Å to about 1000 Å.

After the insulating material 150′ is formed, the substrate 110 on which the pixel electrode 131 and the insulating material 150′ are formed goes through processes including separation, chamfering, washing, curing, etc.

During any of the above processes, the environmental element 160 may be introduced or attached to the insulating material 150′. The environmental element 160 may not be removed by the washing process.

Referring to FIG. 5, the protection insulating layer 150 is formed by removing the insulating material 150′ except for a region at which the environmental element 160 is disposed. Thus, the width wa of the environmental element 160 and the width wb of the protection insulating layer 150 may be substantially the same, within a processing error or tolerance range.

The insulating material 150′ may be removed by a plasma treatment process. Plasma treatment is generally performed before the intermediate layer 132 shown in FIG. 6 is formed, and thus no additional process is necessary for removing the protection insulating layer 150′ of the present embodiment, thereby simplifying a manufacturing process.

Referring to FIG. 6, the intermediate layer 132 is formed on the pixel electrode 131 and the environmental element 160.

The intermediate layer 132 may be formed by utilizing a vapor deposition process. When a step difference between the region at which the environmental element 160 is disposed and a region at which the environmental element 160 is not disposed is great, due to, for example, a large size of the environmental element 160, the intermediate layer 132 may include a separated region (e.g., a cut region).

That is, the separated region 132a of the intermediate layer 132 may be disposed on the environmental element 160.

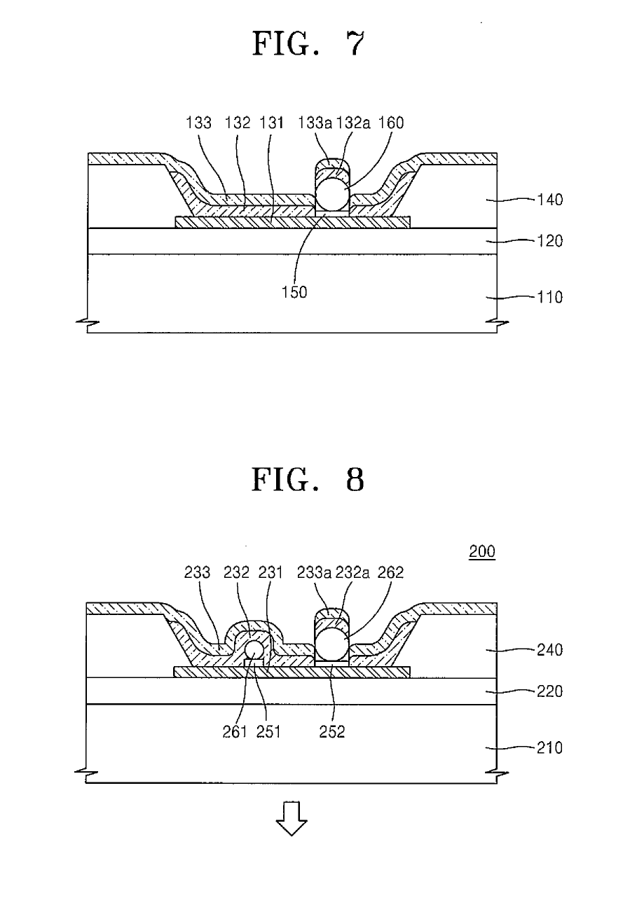

Referring to FIG. 7, the opposing electrode 133 is formed on the intermediate layer 132.

The opposing electrode 133 may be formed by utilizing the vapor deposition process, and may include a separated region (e.g., a cut region) similar to the intermediate layer 132. In this regard, the separated region 133a of the opposing electrode 133 may be formed to cover the separated region 132a of the intermediate layer 132.

The organic light-emitting display apparatus 100 of the present embodiment includes the protection insulating layer 150 blocking a path (e.g., a short circuit path) from the pixel electrode 131 through the separated regions of the intermediate layer 132 and the opposing electrode 133 due to diffusion of a material included in the opposing electrode 133, thereby preventing a phenomenon in which a dark spot is generated (that is, the protection insulating layer 150 prevents the opposing electrode 133 from contacting or shorting the pixel electrode 131).

FIG. 8 is a schematic cross-sectional view of an organic light-emitting apparatus 200 according to another embodiment of the present invention.

Referring to FIG. 8, the organic light-emitting apparatus 200 of the present embodiment includes a pixel electrode 231 disposed on a substrate 210, environmental elements 261 and 262 disposed on the pixel electrode 231, protection insulating layers 251 and 252 disposed between the pixel electrode 231 and the environmental elements 261 and 262 and respectively disposed at regions of the pixel electrode 231 corresponding to the environmental elements 261 and 262, an opposing electrode 233 disposed to face the pixel electrode 231, and an intermediate layer 232 disposed between the pixel electrode 231 and the opposing electrode 233 and including an organic emission layer.

An insulating layer 220 may be disposed between the substrate 210 and the pixel electrode 231.

The environmental elements 261 and 262 may be disposed on or introduced to the pixel electrode 231. The environmental elements 261 and 262 may have different sizes and include materials different from each other.

The protection insulating layers 251 and 252 may be disposed between the pixel electrode 231 and the environmental elements 261 and 262, respectively.

The protection insulating layers 251 and 252 may have substantially the same widths as those of the environmental elements 261 and 262 that are respectively disposed on the protection insulating layers 251 and 252.

The intermediate layer 232 and the opposing electrode 233 may include a separated region (e.g., a cut region). A separated region 232a (e.g., a separated portion) of the intermediate layer 232 and a separated region 233a (e.g., a separated portion) of the opposing electrode 233 may be disposed on the environmental element 262.

When a size of the environmental element 261 is relatively small, the intermediate layer 232 and the opposing electrode 233 may not be separated or cut due to the environmental element 261. In this case, light may be emitted from the intermediate layer 232 corresponding to a region at which the environmental element 261 is disposed.

The other elements are substantially the same as or substantially similar to those of the organic light-emitting apparatus 100 of FIG. 1, and thus descriptions thereof are omitted.

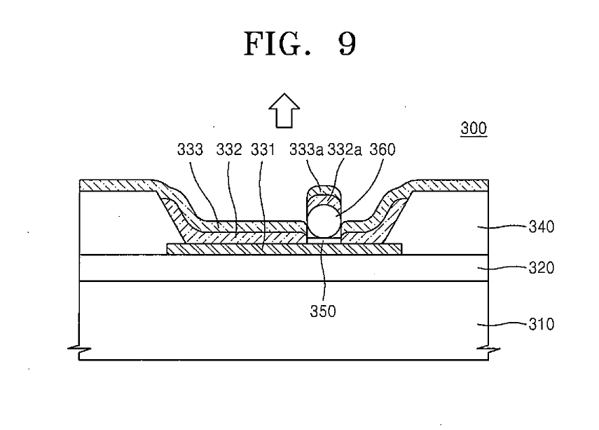

FIG. 9 is a schematic cross-sectional view of an organic light-emitting apparatus 300 according to another embodiment of the present invention.

Referring to FIG. 9, the organic light-emitting apparatus 300 of the present embodiment includes a pixel electrode 331 disposed on a substrate 310, an environmental element 360 disposed on the pixel electrode 331, a protection insulating layer 350 disposed between the pixel electrode 331 and the environmental element 360 and disposed at a region of the pixel electrode 331 corresponding to the environmental element 360, an opposing electrode 333 disposed to face the pixel electrode 331, and an intermediate layer 332 disposed between the pixel electrode 331 and the opposing electrode 333 and including an organic emission layer.

An insulating layer 320 may be disposed between the substrate 310 and the pixel electrode 331.

The pixel electrode 331 may be configured as a reflective electrode that reflects light emitted from the organic emission layer included in the intermediate layer 332 and may include a reflective layer including Al, Mg, Al, Pt, Pd, Au, Ni, Nd, Ir, Cr or compounds thereof. The pixel electrode 331 may also include a transparent or semi-transparent electrode layer formed on the reflective layer.

The transparent or semi-transparent electrode layer may include indium tin oxide (ITO), indium zinc oxide (IZO), zinc oxide (ZnO), indium oxide (e.g., In₂O₃), indium gallium oxide (IGO), and/or aluminum zinc oxide (AZO).

The environmental element 360 may be disposed on or introduced to the pixel electrode 331. The protection insulating layer 350 may be disposed between the environmental element 360 and the pixel electrode 331.

The intermediate layer 332 includes the organic emission layer and may further include at least one of a hole injection layer (HIL), a hole transport layer (HTL), an electron transport layer (ETL), and an electron injection layer (EIL). The present embodiment of the present invention is not limited thereto, and the intermediate layer 332 may include the organic emission layer and may further include various function (e.g., functional) layers.

The opposing electrode 333 may be configured as a semi-transmissive electrode, may include Ag, Al, Mg, LI, Ca, Cu, LiF/Ca, LiF/Al, magnesium/silver (Mg/Ag), and/or calcium/silver (Ca/Ag), and may be formed as a thin film having a thickness in a range of several nm through several tens nm.

Therefore, the organic light-emitting apparatus 300 of the present embodiment may be a top emission display apparatus in which light emitted from the intermediate layer 332 is reflected by the pixel electrode 331 and is emitted in a direction of the opposing electrode 333 (see the arrow in FIG. 9).

The other elements are substantially the same as or substantially similar to those of the organic light-emitting apparatus 100 shown in FIG. 1, and thus descriptions thereof are omitted.

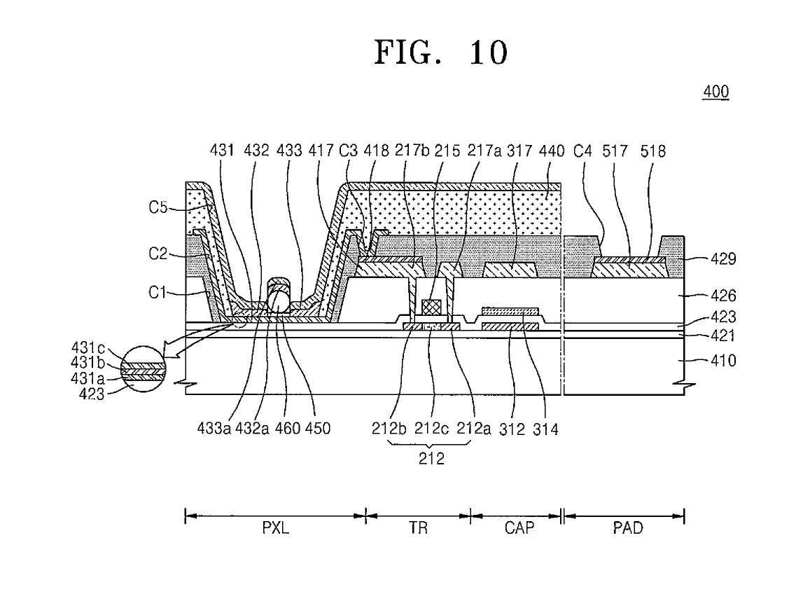

FIG. 10 is a schematic cross-sectional view of an organic light-emitting apparatus 400 according to another embodiment of the present invention.

Referring to FIG. 10, the organic light-emitting apparatus 400 of the present embodiment includes a pixel region PXL including an intermediate layer 432 disposed on a substrate 410, a transistor region TR including at least one thin film transistor, a capacitor region CAP including at least one capacitor, and a pad region PAD.

The substrate 410 may be a glass substrate or a plastic substrate. A buffer layer 421 may be disposed on the substrate 410.

An active layer 212 of the thin film transistor is disposed at the transistor region TR and provided on the buffer layer 421. The active layer 212 may be formed to include various materials. For example, the active layer 212 may include an inorganic semiconductor material, such as amorphous silicon or crystalline silicon. In this case, the active layer 212 may include a channel region 212c,a source region 212a, and a drain region 212b. The source region 212a and the drain region 212b are disposed at both edges of the channel region 212c and are doped with ion impurities. As another example, the active layer 212 may include an oxide semiconductor. As another example, the active layer 212 may include an organic semiconductor material.

A gate electrode 215 is disposed on a first insulating layer 423 at a location corresponding to the channel region 212c of the active layer 212. The first insulating layer 423 is a gate insulating film disposed between the gate electrode 215 and the active layer 212. The gate electrode 215 may have a single layer structure or a multilayer structure including aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper(Cu).

A source electrode 217a and a drain electrode 217b that are respectively connected to the source region 212a and the drain region 212b of the active layer 212 are disposed on a second insulating layer 426. The second insulating layer 426 is an interlayer insulating film disposed between the gate electrode 215 and the source and drain electrodes 217a and 217b. Each of the source electrode 217a and the drain electrode 217b may have a structure of two or more heterogeneous metal layers having electron mobilities different from each other. For example, each of the source electrode 217a and the drain electrode 217b may have a structure of two or more layers including a metal, such as Al, Pt, Pd, Ag, Mg, Au, Ni, Nd, Ir, Cr, Li, Ca, Mo, Ti, W, Cu, and/or alloys of these metal materials.

A third insulating layer 429 is provided on the second insulating layer 426 to cover the source electrode 217a and the drain electrode 217b.

The first insulating layer 423 and the second insulating layer 426 may be configured as single-layer or multilayer inorganic insulating layers. The third insulating layer 429 may be configured as an organic insulating layer.

A pixel defining layer 440 is disposed on the third insulating layer 429. The pixel defining layer 440 may be configured as an organic insulating layer.

The buffer layer 421 and the first insulating layer 423 are disposed on the substrate 410 in the pixel region PXL. A pixel electrode 431 is disposed on the first insulating layer 423 at the pixel region PXL.

The pixel electrode 431 is disposed in an opening C2 formed in the third insulating layer 429. The pixel defining layer 440 including an opening C5, formed in a location corresponding to the opening C2 included in the third insulating layer 429, is disposed at both edges of the pixel electrode 431.

The second insulating layer 426 includes an opening C1 formed at a location corresponding to the opening C2 included in the third insulating layer 429. The opening C1 included in the second insulating layer 426, the opening C2 included in the third insulating layer 429, and the opening C5 included in the pixel defining layer 440 are formed to overlap with each other. The opening C2 included in the third insulating layer 429 may be larger than the opening C5 included in the pixel defining layer 440 and may be smaller than the opening C1 included in the second insulating layer 426.

An end portion of the pixel electrode 431 is disposed on a top surface of the third insulating layer 429 and is covered by the pixel defining layer 440. A part of the pixel electrode 431 is exposed by the pixel defining layer 440.

The third insulating layer 429 may include a contact hole C3 that electrically couples (e.g., electrically connects) the pixel electrode 431 to the source electrode 217a or the drain electrode 217b. A case where the pixel electrode 431 is electrically coupled to (e.g., electrically connected to) the drain electrode 217b is illustrated in the embodiment shown in FIG. 10.

That is, a first contact layer 417 extending from the drain electrode 217b and a second contact layer 418 provided on the first contact layer 417 are disposed at a lower portion of the contact hole C3. The pixel electrode 431 disposed in the contact hole C3 is directly connected to (e.g., contacts) the second contact layer 418 and is electrically coupled to (e.g., electrically connected to) the drain electrode 217b.

The pixel electrode 431 may include a semi-transmissive metal layer 431b. The pixel electrode 431 may further include transparent conductive oxide layers 431a and 431c that are respectively formed at lower and upper portions of the semi-transmissive metal layer 431b and protect the semi-transmissive metal layer 431b.

The semi-transmissive metal layer 431b may be formed of silver (Ag) or a silver alloy. The semi-transmissive metal layer 431b forms a microcavity structure with an opposing electrode 433 (e.g., a reflective electrode) that will be further described later, thereby increasing light efficiency and color purity of the organic light-emitting display apparatus 400.

An environmental element 460 may be disposed on the pixel electrode 431 exposed by the opening C5 included in the pixel defining layer 440. The environmental element 460 may have various components (i.e., may include various materials), such as various organic materials, inorganic materials, combinations of organic and inorganic materials, or the like

The organic light-emitting display apparatus 400 of the present embodiment includes a protection insulating layer 450 disposed between the pixel electrode 431 and the environmental element 460.

That is, the protection insulating layer 450 may be disposed only at a region of the pixel electrode 431 on which the environmental element 460 is disposed. A width of the environmental element 460 and a width of the protection insulating layer 450 may be substantially the same.

When the environmental element 460 is provided on the pixel electrode 431, the protection insulating layer 450 of the present embodiment may prevent the pixel electrode 431 and the opposing electrode 433 from being shorted (that is, may prevent the pixel electrode 431 and the opposing electrode 433 from contacting each other).

When the protection insulating layer 450 is not present or formed and when the environmental element 460 that is thicker than the intermediate layer 432 is provided, the environmental element 460 is not sufficiently covered by the intermediate layer 432, and a region in which the intermediate layer 432 and the opposing electrode 433 are separated (e.g., cut) may be generated.

The opposing electrode 433, including aluminum (Al), may diffuse into the separated region (e.g., the cut region) toward the intermediate layer 432 and the pixel electrode 431. Thus, the pixel electrode 431 and the opposing electrode 433 may be shorted (that is, the pixel electrode 431 and the opposing electrode 433 may contact each other), which causes a phenomenon in which a corresponding sub pixel does not emit light, i.e., a dark spot.

However, the organic light-emitting display apparatus 400 of the present embodiment includes the protection insulating layer 450 that may block a diffusion path of the opposing electrode 433 and prevents the pixel electrode 431 and the opposing electrode 433 from being shorted with each other. Thus, the phenomenon of the dark spot due to the environmental element 460 may be prevented.

The intermediate layer 432 may be disposed on the pixel electrode 431 and the environmental element 460. The intermediate layer 432 includes an organic emission layer and may further include at least one of a HIL, a HTL, an ETL, and an EIL. The embodiment of the present invention is not limited thereto, and the intermediate layer 432 may include the organic emission layer and further various function (e.g., functional) layers.

Although the intermediate layer 432 is disposed only at a bottom of the opening C5 included in the pixel defining layer 440 shown in FIG. 10, this is for convenience of illustration and the present invention is not limited thereto. That is, the organic emission layer included in the intermediate layer 432 may be extended and formed at a top surface of the pixel defining layer 440 along an etch surface of the opening C5 included in the pixel defining layer 440 as well as at the bottom of the opening C5. Function layers included in the intermediate layer 432 may be extended to other pixels.

The opposing electrode 433 may be disposed on the intermediate layer 432.

The opposing electrode 433 may be configured as a reflective electrode including a reflective material, and may include Al, Mg, Li, Ca, LiF/Ca, and/or LiF/Al.

Therefore, the organic light-emitting display apparatus 400 of the present embodiment may be a bottom emission display apparatus in which light emitted from the intermediate layer 432 is reflected by the opposing electrode 433, transmits through the pixel electrode 431, and is emitted in a direction of the substrate 410.

The intermediate layer 432 and the opposing electrode 433 may each include a separated region (e.g., a cut region) due to step differences created by the protection insulting layer 450 and the environmental element 460. That is, a separated region 432a (e.g., a separated portion) of the intermediate layer 432 and a separated region 433a (e.g., a separated portion) of the opposing electrode 433 may be disposed on the protection insulting layer 450 and the environmental element 460.

Therefore, no voltage is applied to the region 433a of the opposing electrode 433 disposed on the environmental element 460, and thus no light may emit from the region 432a of the intermediate layer 432 corresponding to the region 433a of the opposing electrode 433. However, a region from which no light emits is a relatively very small region, and light emits from a region in which the environmental element 460 is not disposed, and thus a phenomenon in which entire corresponding sub pixels do not emit light is prevented.

The buffer layer 421 is disposed on the substrate 410 in the capacitor region CAP. A capacitor including a first electrode 312 disposed on the same layer as the active layer 212, a second electrode 314 disposed on the same layer as the gate electrode 215, and a third electrode 317 disposed on the same layer as the source electrode 217a and the drain electrode 217b is provided on the buffer layer 421 in the capacitor region CAP.

The first electrode 312 of the capacitor may be formed as a semiconductor doped with ion impurities, similar to (or like) the source area 212a and the drain area 212b of the active layer 212.

The second electrode 314 of the capacitor is disposed on the first insulating layer 423 in the same layer as the gate electrode 215, whereas materials of the second electrode 314 and the gate electrode 215 are different from each other. The material of the second electrode 314 may include the transparent conductive oxide. Ion impurities are doped on the first electrode 312 through the second electrode 314, thereby forming the capacitor having a metal-insulator-metal (MIM) structure.

The third electrode 317 of the capacitor may be formed of the same material as those of the source electrode 217a and the drain electrode 217b. A plurality of capacitors that are connected in parallel to each other are formed by using the first electrode 312, the second electrode 314, and the third electrode 317, thereby increasing a capacitance of the organic light-emitting display apparatus 400 without increasing an area of the capacitor. Thus, the area of the capacitor may be reduced as the capacitance increases, thereby increasing an aperture ratio.

A first pad layer 517 and a second pad layer 518 are disposed on the second insulating layer 426 in the pad region PAD.

The first pad layer 517 may include a plurality of metal layers having electron mobilities different from each other like the source electrode 217a and drain electrode 217b. For example, the first pad layer 517 may have a multilayer structure including one or more metal materials, such as aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper(Cu).

The second pad layer 518 may be formed of a transparent conductive oxide and may prevent the first pad layer 517 from being exposed to moisture and oxygen, thereby preventing a deterioration of reliability of a pad. The second pad layer 518 may be formed of the same material and on the same layer as that of the second contact layer 418 disposed at the lower portion of the contact hole C3.

The first pad layer 517 is not exposed to an etchant during a process of etching the pixel electrode 431 because the second pad layer 518 that is a protection layer is formed on an upper portion of the first pad layer 517.

Moreover, end portions of the first pad layer 517 that are sensitive to an external environment including, for example, moisture or oxygen, are covered by the third insulating layer 429, and thus, the end portions of the first pad layer 517 are not also exposed to the etchant during the process of etching the pixel electrode 431.

Meanwhile, the organic light-emitting display apparatus 400 according to the present embodiment may further include a sealing member that seals (e.g., that is configured to seal) a display region including the pixel region PXL, the transistor region TR, and the capacitor region CAP. The sealing member may be formed as a substrate including, for example, a glass member, a plastic member, a metal film, or a thin film encapsulation formed by alternately disposing an organic insulating film and an inorganic insulating film.

As described above, aspects of the one or more of the above embodiments of the present invention provide the organic light-emitting display apparatus and method of manufacturing the same that may reduce or prevent dark spot generation.

It should be understood that the example embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims and their equivalents.

What is claimed is:

1. An organic light-emitting display apparatus comprising:
a pixel electrode on a substrate;
an environmental element on the pixel electrode;
a protection insulating layer between the pixel electrode and the environmental element and at a location corresponding to the environmental element;
an opposing electrode facing the pixel electrode; and
an intermediate layer between the pixel electrode and the opposing electrode and comprising an organic emission layer.

2. The organic light-emitting display apparatus of claim 1, wherein a width of the protection insulating layer is substantially the same as that of the environmental element.

3. The organic light-emitting display apparatus of claim 1, wherein the protection insulating layer is between the pixel electrode and the intermediate layer.

4. The organic light-emitting display apparatus of claim 1, wherein the protection insulating layer comprises polyimide (PI), silicon oxide, and/or silicon nitride.

5. The organic light-emitting display apparatus of claim 1, wherein the protection insulating layer has a thickness in a range from about 700 Å to about 1000 Å.

6. The organic light-emitting display apparatus of claim 1, wherein the opposing electrode and the intermediate layer each comprise separated regions due to the environmental element.

7. The organic light-emitting display apparatus of claim 1, further comprising:
a thin film transistor electrically coupled to the pixel electrode and comprising an active layer, a gate electrode, a source electrode, a drain electrode, a first insulating layer between the active layer and the gate electrode, and a second insulating layer between the gate electrode and the source and drain electrodes;
a pad electrode comprising a first pad layer on a same layer as the source and drain electrodes, and a second pad layer on the first pad layer;
a third insulating layer covering the source and drain electrodes and both edges of the pad electrode and having an opening, the pixel electrode being in the opening; and
a pixel defining layer having an opening at a location corresponding to the opening in the third insulating layer, the pixel defining layer covering both edges of the pixel electrode.

8. The organic light-emitting display apparatus of claim 7, further comprising:
a capacitor comprising a first electrode on a same layer as the active layer;
a second electrode on a same layer as the gate electrode; and
a third electrode on a same layer as the source and drain electrodes.

9. The organic light-emitting display apparatus of claim 7, wherein the pixel electrode comprises a transparent conductive oxide layer and a semi-transmissive metal layer comprising silver (Ag) or a silver alloy, and
wherein the opposing electrode comprises a reflective metal layer.

10. The organic light-emitting display apparatus of claim 7, wherein the second insulating layer has an opening at a region corresponding to the opening in the third insulating layer,
wherein the opening in the second insulating layer, the opening in the third insulating layer, and the opening in the pixel defining layer overlap with each other, and
wherein the opening in the third insulating layer is larger than the opening in the pixel defining layer and is smaller than the opening in the second insulating layer.

11. The organic light-emitting display apparatus of claim 10, wherein an end portion of the pixel electrode is on a top surface of the third insulating layer.

12. The organic light-emitting display apparatus of claim 7, wherein the third insulating layer has a contact hole to electrically couple the pixel electrode with the source electrode or the drain electrode,
wherein a first contact layer is electrically coupled to the source electrode or the drain electrode, and a second contact layer is on the first contact layer and comprises a same material as that of the second pad layer, the first and second contact layers being disposed at a lower portion of the contact hole,
wherein a portion of the pixel electrode is at the contact hole, and
wherein the pixel electrode and the second contact layer are directly connected to each other.

13. A method of manufacturing an organic light-emitting display apparatus, the method comprising:
forming a pixel electrode on a substrate;
forming an insulating material on the pixel electrode;
forming a protection insulating layer by removing the insulating material except for a region at which an environmental element is located;
forming an intermediate layer on the pixel electrode and the environmental element; and
forming an opposing electrode on the intermediate layer.

14. The method of claim 13, further comprising:
after the forming of the pixel electrode, forming a pixel defining layer having an opening exposing a portion of the pixel electrode,
wherein the forming of the insulating material comprises forming the insulating material on the pixel defining layer and on the portion of the pixel electrode exposed by the pixel defining layer.

15. The method of claim 13, wherein the insulating material is formed of polyimide (PI), silicon oxide, and/or silicon nitride.

16. The method of claim 13, wherein the insulating material has a thickness in a range from about 700 Å to about 1000 Å.

17. The method of claim 13, wherein the insulating material is formed by printing.

18. The method of claim 13, wherein the intermediate layer and the opposing electrode are formed by vapor deposition.

19. The method of claim 13, wherein the protection insulating layer is formed by removing the insulating material by plasma treatment.
